(19) United States
(12) Patent Application Publication
(10) Pub. No.: US 2017/0141074 A1
(43) Pub. Date: May 18, 2017

(54) METAL PREPARATION FOR CONNECTING COMPONENTS

(71) Applicant: Heraeus Deutschland GmbH & Co. KG, Hanau (DE)

(72) Inventors: Michael SCHÄFER, Künzell (DE); Wolfgang SCHMITT, Rodgau (DE)

(21) Appl. No.: 15/320,959

(22) PCT Filed: May 26, 2015
(86) PCT No.: PCT/EP2015/061567

§ 371 Date: Dec. 21, 2016

(30) Foreign Application Priority Data
Jun. 27, 2014 (EP) 14174684.2

(51) Int. Cl. H01L 23/00; B23K 35/02; B22F 1/02; B23K 35/30; B22F 1/00; B23K 1/00; B23K 35/36

(52) U.S. Cl. CPC H01L 24/83; B23K 1/0016; B23K 35/025; B23K 35/3615; B23K 35/3006; B22F 1/0055; B22F 1/02; H01L 24/32; B23K 2201/40

(57) ABSTRACT

A metal preparation is provided which contains (A) 40 to <80% by weight of at least one metal in the form of particles having a coating that contains at least one organic compound, and (B) >20 to 50 by weight organic solvent.

### CROSS-REFERENCE TO RELATED APPLICATIONS

This application is a Section 371 of International Application No. PCT/EP20151061567, filed May 26, 2015, which was published in the German language on Dec. 30, 2015 under International Publication No. WO 2015/197281 A1 and the disclosure of which is incorporated herein by reference.

### BACKGROUND OF THE INVENTION

In power and consumer electronics, the connecting of components, such as LEDs or very thin silicon chips that are highly pressure and temperature sensitive, is particularly challenging.

For this reason, these pressure- and temperature-sensitive components are often connected to each other by gluing. However, adhesive technology is associated with a disadvantage in that it produces contact sites between the components that provide only insufficient heat conductivity and/or electrical conductivity.

In order to solve this problem, the components to be connected are often subjected to sintering. Sintering technology is a very simple method for connecting components in stable manner. It involves the use of so-called sintering pastes which are applied by printing processes, such as stencil printing or screen printing, or by dispensing.

Working with conventional metal sintering pastes reaches its limits as soon as components with a problematic surface nature are to be connected by the sintering process.

### BRIEF SUMMARY OF THE INVENTION

The present invention relates to a metal preparation, and to a method for connecting components, in which metal preparation is used.

### DETAILED DESCRIPTION OF THE INVENTION

It is the object of the invention to provide a sintering method for the stable connecting of components, in particular of components having a problematic surface nature. In the scope of the invention, components with a problematic surface nature shall be understood to mean components having a non-planar and/or suctioning and/or open-pore surface and/or a complicated surface topography. In the scope of the invention, components with a problematic surface nature shall be understood to mean, in particular, components having a surface with indentations (cavities) and/or bulges and/or curvatures and/or corrugations and/or a rough surface.

The method is to be used to produce contact sites of low porosity and high electrical and thermal conductivity between components to be connected. It is another object of the present invention to provide a metal preparation that is well-suited for implementing this sintering method.

The invention relates to a method for connecting components, which comprises (a) providing a sandwich arrangement that comprises at least (a1) one component 1, (a2) one component 2, and (a3) a sintering agent that is situated between component 1 and component 2, and (b) sintering the sandwich arrangement, characterized in that the sintering, agent was applied by spray application from a metal preparation comprising (A) 40 to <80% by weight of at least one metal that is present in the form of particles that comprise a coating that contains at least one organic compound, and (B) >20 to 50% by weight organic solvent.

A metal preparation according to the invention comprises (A) 40 to <80% by weight of at least one metal that is present in the form of particles that comprise a coating that contains at least one organic compound and (B) >20 to 50% by weight organic solvent.

The metal preparation according to the invention contains 40 to <80% by weight, preferably 50 to <80% by weight, more preferably 60 to 75% by weight, of at least one metal that is present in the form of particles that comprise a coating that contains at least one organic compound. The weights given presently include the weight of the coating compounds situated on the particles.

The term “metal” shall include both pure metals and metal alloys. In the scope of the invention, the term “metal” refers to elements in the Periodic Table of the elements that are in the same period as boron, but to the left of boron, in the same period as silicon, but to the left of silicon, in the same period as germanium, but to the left of germanium, and in the same period as antimony, but to the left of antimony, as well as all elements having an atomic number of more than 55.

In the scope of the invention, pure metals shall be understood to be metals containing a metal with a purity of at least 95% by weight, preferably at least 98% by weight, more preferably at least 99% by weight, and even more preferably at least 99.9% by weight.

According to a preferred embodiment, the metal is copper, silver, gold, nickel, palladium, platinum or aluminum, in particular silver.

Metal alloys shall be understood to be metallic mixtures of at least two components of which at least one is a metal.

According to a preferred embodiment, an alloy containing copper, aluminum, nickel and/or precious metals is used as a metal alloy. The metal alloy preferably comprises at least one metal selected from the group consisting of copper, silver, gold, nickel, palladium, platinum, and aluminum. Particularly preferred metal alloys contain at least two metals selected from the group consisting of copper, silver, gold, nickel, palladium, platinum, and aluminum. Moreover, it can be preferred that the fraction of metals selected from the group consisting of copper, silver, gold, nickel, palladium, platinum, and aluminum accounts for at least 90% by weight, preferably at least 95% by weight, more preferably at least 99% by weight, and even more preferably 100% by weight of the metal alloy. The alloy can be, for example, an alloy that contains copper and silver; copper, silver, and gold; copper and gold; silver and gold; silver and palladium; platinum and palladium; or nickel and palladium.

The metal preparation according to the invention can contain, as metal, a pure metal, multiple types of pure metals, a type of metal alloy, multiple types of metal alloys or mixtures thereof.

The metal is present in the metal preparation in the form of particles.

The metal particles can differ in shape. The metal, particles can be present, for example, in the form of flakes or can be of a spherical (ball-like) shape. According to a particularly preferred embodiment, the metal particles take the shape of flakes. However, this does not exclude a minor fraction of the particles employed being of different shape. Preferably at least 70% by weight, more preferably at least 80 by weight, even more preferably at least 90% by weight or 100% by weight, of the particles are present in the form of flakes.

The metal particles are coated. The term “coating of particles” shall be understood to refer to a firmly adhering layer on the surface of particles. The coating of the metal particles contains at least one type of coating, compound which is an organic compound. The organic compounds serving as coating compounds are carbon-containing compounds that prevent the metal particles from agglomerating.

According to a preferred embodiment, the coating compounds bear at least one functional group. Conceivable functional groups include, in particular, carboxylic acid groups, carboxylate groups, ester groups, kern groups, aldehyde groups, amino groups, amide groups, azo groups, imide groups or nitrile groups.

Carboxylic acid groups and carboxylic acid ester groups are preferred functional groups. The carboxylic acid group can be deprotonated.

The coating compounds with at least one functional group are preferably saturated, mono-unsaturated, or poly-unsaturated organic compounds.

Moreover, these coating compounds with at least one functional group can be branched or non-branched.

The coating compounds with at least one function of preferably comprise 1 to 50, more preferably 2 to 24, even more preferably 6 to 24, and yet more preferably 8 to 20 carbon atoms.

The coating, compounds can be ionic or non-ionic.

It is preferable to use free fatty acids, fatty acid salts or fatty acid esters as coating compounds. The free fatty acids, fatty acid salts, and fatty acid esters preferably are non-branched. Moreover, the free fatty acids, fatty acid salts, and fatty acid esters are preferably saturated.

Preferred fatty acid salts include the ammonium, monoalkylammonium dialkylammonium, trialkylammonium, aluminum, copper, lithium, sodium, and potassium salts.

Alkyl esters, in particular methyl esters, ethyl esters, propyl esters, and butyl esters, are preferred esters.

According to a preferred embodiment, the free fatty acids, fatty acid salts or fatty acid esters are compounds with 8 to 24, more preferably 10 to 24, and even more preferably 12 to 18 carbon atoms.

Preferred coating compounds include caprylic acid (octanoic acid), capric acid (decanoic acid), lauric acid (dodecanoic acid), myristic acid (tetradecanoic acid), palmitic acid (hexadecanoic acid), margaric acid (heptadecanoic acid), stearic acid (octadecanoic acid), arachinic acid (eicosanoic acid/icosanoic acid), behenic acid (docosanoic acid), lignoceric acid (tetracosanoic acid) as well as the corresponding esters and salts.

Particularly preferred coating compounds include dodecanoic acid, octadecanoic acid, aluminum stearate, copper stearate, sodium stearate, potassium stearate, sodium palmitate, and potassium palmitate.

The coating compounds can be applied to the surface of the metal particles b conventional methods that are known from the prior art.

It is possible, for example, to slurry the coating compounds, in particular the stearates or palmitates mentioned above, in solvents and to triturate the slurried coating compounds together with the metal particles in ball mills. After trituration, the metal particles, which are coated with the coating compounds, are dried and then dust is removed.

Preferably, the fraction of organic compounds, in particular the fraction of compounds selected from the group consisting of free fatty acids, fatty acid salts or fatty acid esters with 8 to 24, more preferably 10 to 24, and even more preferably 12 to 18 carbon atoms, of the entire coating is at least 60% by weight, more preferably at least 70%, even more preferably at least 80% by, yet more preferably at least 90% by weight, in particular at least 95% by weight, at least 99% by weight or 100% by weight.

Usually, the fraction of the coating compounds, preferably of the coating compounds selected from the group consisting of free fatty acids, fatty acid salts or fatty acid esters with 8 to 24, more preferably 10 to 24, and even more preferably 12 to 18 carbon atoms, is 0.01 to 2 by weight, preferably 0.3 to 1.5% by weight, with respect to the weight of the coated metal particles.

The degree of coating, defined as the ratio of the mass of coating compounds to the surface area of the metal particles, is preferably 0.00005 to 0.03 g, more preferably 0.0001 to 0.02 g of coating compounds per square meter (m²) of surface area of the metal particles.

The metal preparation according to the invention contains >20 to 50% by weight, preferably 25 to 40% by weight organic solvent (B), i.e., an organic solvent or a mixture of at least two organic solvents.

The organic solvent or solvents are organic solvents that are commonly used as ingredients of metal sintering pastes that are known to a person skilled in the art and have been mentioned above. Examples include terpineols, N-methyl-2-pyrrolidone, ethylene dimethylacetamide, 1-tridecanol, 2-tridecanol, 3-tridecanol, 4-tridecanol, 5-tridecanol, 6-tridecanol, isotridecanol, with the exception of a methyl substitution on the penultimate C-atom, unsubstituted 1-hydroxy-C16-C20-alkanes such as 16-methylheptadecan-1-ol, dibasic esters (preferably dimethylesters of elutaric, adipic or succinic acid or mixtures thereof), glycerol, diethylene glycol, triethylene glycol, and aliphatic hydrocarbons, in particular saturated aliphatic hydrocarbons, having 5 to 32 C-atoms, more preferably 10 to 15 C-atoms, and even more preferably 10 to 13 C-atoms. Said aliphatic hydrocarbons are being marketed, for example, by Exxon Mobil by the brand name of Exxsol or by the brand name of Isopar M.

The metal preparation according to the invention can contain 0 to 12% by weight, preferably 0.1 to 12 by weight, more preferably 1 to 10% by weight, and even more preferably 2 to 8% by weight of at least one metal precursor (C).

In the scope of the invention, a metal precursor shall be understood to mean a compound that contains at least one metal and can be decomposed while releasing the metal. Preferably, this includes a compound that decomposes at temperatures below 200° C. while releasing the metal. Accordingly, the use of a metal precursor in the sintering process is preferably associated with the in situ production of a metal. It is easy to determine whether a compound is a metal precursor. For example, a preparation containing a compound to be tested can be deposited on a substrate having a silver surface, followed by heating to 200° C., and maintaining this temperature for 20 minutes. Then, it is tested whether or not the compound to be tested decomposed under these conditions. For this purpose, for example, the content of the metal-containing components of the preparation can be weighed before the test to calculate the theoretical mass of metal. After the test, the mass of the material deposited on the substrate is determined by gravimetric methods. If the mass of the material deposited on the substrate is equal to the theoretical mass of metal, taking into account the usual measuring inaccuracy, the tested compound is a metal precursor.

According to a preferred embodiment, the metal precursor is a metal precursor that can be decomposed endothermically. A metal precursor that can be decomposed endothermically shall be understood to be a metal precursor whose thermal decomposition, preferably in a protective gas atmosphere, is an endothermic process. This thermal decomposition is to be associated with the release of metal from the metal precursor.

According to another preferred embodiment, the metal precursor comprises a metal that is also present in the particulate metal (A).

The metal precursor preferably comprises, as metal, at least one element selected from the group consisting of copper, silver, gold, nickel, palladium, and platinum.

It can be preferred to use, as metal precursor, decomposable carbonates, lactates, formates, citrates, oxides or fatty acid salts, preferably fatty acid salts having 6 to 24 carbon atoms, of the metals specified above.

In specific embodiments, silver carbonate, silver(I) lactate, silver(II) formate, silver citrate, silver oxide (for example, AgO or Ag₂O), copper(II) lactate, copper stearate, copper oxides (for example, Cu₂O or CuO) or gold oxides (for example, Au₂O or AuO) are used as metal precursors.

According to a particularly preferred embodiment, silver carbonate, silver(I) oxide or, silver(II) oxide is used as metal precursor.

The metal precursor, if present in the metal preparation, is preferably present in the form of particles.

The metal precursor particles can take the shape of flakes or a spherical (ball-like) shape. Preferably, the metal precursor particles are present in the form of flakes.

Moreover, the metal preparation according to the invention can contain 0 to 10% by weight, preferably 0 to 8% by weight, of at least one sintering aid (D). Examples of sintering aids include organic peroxides, inorganic peroxides, and inorganic acids, such as are described, for example, in WO2011/026623 A1.

In addition to ingredients (A) to (D) explained above, the metal preparation according to the invention can contain 0 to 15% by weight, preferably 0 to 12% by weight, more preferably 0.1 to 10% by weight, of one or more further ingredients (E). These further ingredients are preferably ingredients that are used commonly in metal sintering pastes. The metal preparation according to the invention can contain, for example, as further ingredients, dispersion agents, surfactants, de-foaming agents, binding agents, polymers such as cellulose derivatives, for example methylcellulose, ethylcellulose, ethylmethylcellulose carboxycellulose, hydroxypropylcellulose, hydroxyethylcellulose, hydroxymethylcellulose and/or viscosity-controlling (rheological) agents.

Accordingly, the metal preparation according to the invention contains, aside from ingredients (A) and (B), 0 to 12% by weight of at least one metal precursor (C), 0 to 10% by weight of at least one sintering aid (D), and 0 to 15% by weight of one or more further ingredients (E) selected from dispersion agents, surfactants, de-foaming agents, binding agents, polymers and/or viscosity-controlling (rheological) agents. In one embodiment, the metal preparation according to the invention consists of ingredients (A) and (B) as well as 0 to 12% by weight of at least one metal precursor (C), 0 to 10% by weight of at least one sintering aid (D), and 0 to 15% by weight of one or more further ingredients (E) selected from dispersion agents, surfactants, de-foaming agents, binding agents, polymers and/or viscosity-controlling (rheological) agents.

The sum of the % by weight fractions specified for ingredients (A) to (E) can be, for example, 100% by weight with respect to the metal preparation according to the invention, i.e., prior to the spray application thereof. Accordingly, the metal preparation according to the invention can be produced by mixing ingredients (A) to (E). Common devices known to a person skilled in the art, such as stirrers, can be used in this context. Alternatively, ingredients (A), part of (B) and (C) to (D) can be mixed through the use of, for example, stirrers and/or three-roller mills, followed by completing the mixing by adding the remaining fraction of (B).

The viscosity of the metal preparation according to the invention is appropriate for spray application thereof. The viscosity is in the range of, for example, 1 to 3 Pa·s, preferably 1.2 to 2 Pa·s, measured in accordance with DIN 53018 (at 23° C., CSR measurement at a shear rate of D=10 s−1). The metal preparation according to the invention can be used for production of a sintering agent, in particular in the form of a layer of a sintering agent, by spray application, and can therefore be used in a sintering process. Sintering shall be understood to mean the connecting of two or more components by heating without the metal particles (A) reaching the liquid phase.

Accordingly, the present invention, as mentioned above, relates to a method for the connecting of components, which comprises (a) providing a sandwich arrangement that comprises at least (a1) one component 1, (a2) one component 2, and (a3) a sintering agent that is situated between the components (between the surfaces and/or surface fractions of the components forming contact surfaces), and (b) sintering the sandwich arrangement, characterized in that the sintering agent made of a metal preparation comprising (A) 40 to <80% by weight of at least one metal that is present in the form of particles that comprise a coating that contains at least one organic compound, and (B) 20 to 50% by weight organic solvent was applied by spraying.

Accordingly, the method according to the invention comprises the steps of
(i) providing at least two components 1 and 2;
(ii) spray application of the metal preparation according to the invention onto a surface or surface fraction of at least one of the components, forming a contact surface while forming the sintering agent;
(iii) forming the sandwich arrangement by connecting the components with the sintering agent; and
(iv) sintering the sandwich arrangement.

The sintering method performed through the use of the sintering agent produced by spray application from the metal preparation according to the invention, in particular through the use of the sintering agent that is present in the form of a layer, can be performed with or without applying pressure. Being able to implement the sintering method without pressure means that a sufficiently firm connection of the components is attained despite foregoing the application of mechanical pressure. Being able to implement the sintering process without pressure allows pressure-sensitive, for example fragile components or components with a mechanically sensitive micro-structure, to be used in the sintering method. Electronic components that have a mechanically sensitive micro-structure suffer electrical malfunction when exposed to inadmissible pressure.

Connecting at least two components shall be understood to mean attaching a first component onto a second component. In this context, “on” simply means that a contact surface of the first component is being connected to a contact surface of the second component regardless of the relative disposition of the two components or of the arrangement containing the at least two components.

In the scope of the invention, the term “component” preferably comprises single parts. Preferably, these single parts cannot be disassembled further.

According to specific embodiments, the term “components” refers to components that are used in electronics.

Accordingly, the components can be, for example, diodes, LEDs (light-emitting diodes), DCB (direct copper bonded) substrates, lead frames, MIDs (molded interconnect devices), dies, IGBTs (insulated-gate bipolar transistors), ICs (integrated circuits), sensors, connection elements (e.g. clips), heat sink elements (preferably aluminum heat sink elements or copper heat sink elements) or other passive components (for example, resistors, capacitors or coils).

The components to be connected can be identical or different components.

It is a particular advantage of the present invention that the components do not necessarily have to have a planar surface or, to be more precise, do not necessarily have to have a planar contact surface by which the sandwich arrangement is formed and/or by which the sintering connection between the components is effected. Instead, the present invention provides the option of joining even components with a problematic surface nature by their non-planar and/or suctioning and/or open-pore and/or complicated surface topography-comprising surfaces and/or surface fractions to other components to form said sandwich arrangements and/or to connect them with sintering methods.

Embodiments of the invention relate to connections of LED to lead frame, LED to ceramic substrate, of dies, diodes, IGBTs or ICs to lead frames, ceramic substrates or DCB substrates, of sensor to lead frame or ceramic substrate. The connection can involve aluminum, copper or silver contact surfaces of the components to aluminum, copper or silver contact surfaces of the substrates, i.e. for example aluminum-copper, aluminum-silver, aluminum-aluminum, copper-silver, copper-copper or silver-silver connections can be formed.

As mentioned in the preceding paragraph, the components—in as far as they do not consist of metal anyway—can, comprise at least one metallization layer. This metallization layer preferably is part of the component. Preferably, this metallization layer is situated on at least one surface of the component.

The components are preferably connected by this metallization layer and/or layers with the sintering agent prepared from the metal preparation according to the invention by spray application.

The metallization layer can comprise pure metal. Accordingly, it can be preferred for the metallization layer to comprise at least 50% by weight, more preferably at least 70% by weight, even more preferably at least 90% by weight or 100% by weight of pure metal. The pure metal is selected, for example, from the group consisting of aluminum, copper, silver, gold, palladium, and platinum.

On the other hand, the metallization layer can just as well comprise an alloy. The alloy of the metallization layer preferably contains at least one metal selected from the group consisting of aluminum, silver, copper, gold, nickel, palladium, and platinum.

The metallization layer can just as well have a multi-layer structure. Accordingly, it can be preferred that at least one surface of the components to be connected comprises a metallization layer made of multiple layers that comprise the pure metals and/or alloys specified above.

In the method according to the invention, at least two components are connected to each other through sintering.

For this purpose, the two components are first made to contact each other. The contacting is effected in this context with the sintering agent that is applied by spray application of the metal preparation according to the invention. For this purpose, a sandwich arrangement is provided, in which sintering agent produced from the metal preparation according to the invention, i.e., is applied by spray application, is situated between each two of the at least two components. In other words, the metal preparation according to the invention is applied by spray application onto at least one of the at least two components and/or onto a contact surface of one of the at least two components in order to prepare the sintering agent, or to be more precise, in order to prepare a layer of the sintering agent.

Accordingly, if two components 1 and 2 are to be connected to each other, the sintering agent produced from the metal preparation according to the invention, i.e., the sintering agent applied by spray application, is situated between component 1 and component 2 and/or bet keen contact surfaces of the two components before the actual sintering. On the other hand, it is, conceivable to connect more than two components to each other. For example, three components, i,e., component 1, component 2, and component 3, can be connected to each other in appropriate manner such that component 2 is situated between component 1 and component 3. In this case, the sintering agent produced by spray application from the metal preparation according to the invention is situated both between component 1 and component 2 as well as between component 2 and component 3.

The individual components are present in a sandwich arrangement and are connected to each other. Sandwich arrangement shall be understood to mean an arrangement in which two components are situated one above the other, whereby the components can be arranged, for example, parallel with respect to each other.

The sandwich arrangement made of at least two components and sintering agents situated in between them can be produced by, firstly, providing a contact surface, in the form of at least one fraction of a surface, for example of a non-planar and/or suctioning and/or open-pore and or complicated surface topography-comprising surface of a component 1 with the sintering agent and/or a layer of the sintering agent by spray application of the metal preparation according to the invention. In this context, it can be expedient to heat the corresponding component and/or the contact surface thereof that is provided with the sintering agent before and/or during the spray application, for example to a temperature above room temperature up to 150° C., preferably 80 to 120° C. This can support the removal or evaporation of organic solvent from the metal preparation according to the invention as early as during the spray application. After the spray coating of component 1 and a drying step, which may be performed and is described below, the other component 2 can be placed, by its contact surface, on the sintering agent layer formed as described above while forming the sandwich arrangement. In this context, the contact surface of component 2 can be uncoated or can comprise a sintering agent layer formed analogous to the procedure used for component 1.

The term, “spray application”, is used in the present description and in the claims, in the context of the application of the preparation according to the invention for the purpose of producing the sintering agent and/or a layer of the sintering agent. Spray application here means a non-contact application method proceeding while nebulizing the metal preparation according to the invention, such as inkjet application, pneumatic spraying or airless spraying. During inkjet application, printing devices that are common in inkjet printing can be used as spraying organs.

During pneumatic and airless spraying, spraying organs that are common in coating technology, such as spraying pistols, can be used. Spraying application can be effected manually or with a coating machine or robot The coating process can proceed in one or multiply repeated steps. A process of spray application performed in multiply repeated steps allows the layer thickness of the sintering agent layer to be formed as desired. Sites of the component or components not to be coated can be covered suitably during the coating process, for example with tape or by covering with stencils.

As mentioned, following the spray application of the metal preparation according to the invention, the surface and/or contact surface of the one component provided with the sintering agent is contacted, with the sintering agent, to a surface and/or contact surface of the component to be connected to it. Accordingly, a sintering agent layer applied by spray application from the metal preparation according to the invention is situated between the components to be connected.

Preferably, the thickness of the wet layer of sintering agent between components to be connected is in the range of 10 to 100 μm, more preferably 20 to 40 μm. The thickness of the wet layer shall be understood to mean the distance between the opposite surfaces and/or contact surfaces of the components to be connected prior to drying, if any, and prior to sintering. The thickness of the wet sintering agent layer can be adjusted as desired by the number of coating steps and/or the flow rate (volume of metal preparation according to the invention spray-applied per unit time) and/or the motion speed of the spray organ(s) used in the process.

Droplets are formed during spray application of the metal preparation according to the invention and release organic solvent to the ambient air on their way from the spray organ to the component surface to be coated. In other words., the fraction of organic solvent has decreased by the time of impact on the component surface to be coated, for example by 30 to 70%, relative to the original fraction of organic solvent in the metal preparation according to the invention, i.e. relative to the metal preparation ready for spray application. For example, the content of organic solvents in sintering agent right after spray application from the metal preparation according to the invention is 10 to 20 percent by weight.

As mentioned above, a drying step, i.e., a removal of organic solvent from the sintering agent, can be performed before the sintering. According to an embodiment, the fraction of organic solvent in the sintering agent after this drying is, for example, 0 to 5% by weight, relative to the original fraction of organic solvent in the metal preparation according to the invention. In other words, according to this embodiment, for example 95 to 100% by weight of the organic solvent or solvents originally present in the metal preparation according to the invention are removed during this drying.

If drying takes place in a sintering process without pressure, the drying can proceed after producing the sandwich arrangement, after contacting the components to be connected. If drying takes place in a sintering process involving the application of pressure, the drying can just as well proceed after spray application of the metal preparation according to the invention onto the at least one surface of the component and before contacting to the component to be connected.

Preferably, the drying temperature is in the range of 50 to 150° C. (object temperature).

Obviously, the drying time depends on the composition of the metal preparation according to the invention and/or the composition of the layer of sintering agent produced from it by spray application, and on the size of the connecting surface of the sandwich arrangement to be sintered The drying times are in the range of, for example, 5 to 45 minutes.

The sandwich arrangement consisting of the at least two components and the sintering agent situated between them is finally subjected to a sintering process.

The actual sintering proceeds are a temperature of, for example, 200 to 250° C. in a process either with or without pressure.

The process pressure in pressure sintering is preferably less than 40 MPa and more preferably less than 5 MPa. For example, the process pressure is in the range of 1 to 30 MPa and more preferably is in the range of 1 to 5 MPa.

The sintering time is, for example, in, the range of 2 to 60 minutes, for example in the range of 2 to 5 minutes in pressure sintering and for example in the range of 30 to 60 minutes in sintering without pressure.

The sintering process can take place in an atmosphere that is not subject to any specific limitations. Accordingly, on the one hand, the sintering can take place in an atmosphere that contains oxygen. On the other hand, it is just as feasible that the sintering takes place in an oxygen-free atmosphere. In the scope of the invention, an oxygen-free atmosphere shall be understood to mean an atmosphere whose oxygen content is no more than 10 ppm, preferably no more than 1 ppm, and even more preferably no more than 0.1 ppm.

The sintering takes place in a conventional suitable apparatus for sintering, in which the above-mentioned process parameters can be set.

The sintering connections produced with the method according to the invention and/or through the use of the metal preparation according to the invention have been found to contain no or a relatively small extent of voids both inside and towards the component contact surface, which is beneficial for the adhesion, strength, and heat conductivity of the sintering connection. Moreover, it has been found that the method according to the invention leads to a largely horizontal orientation, i.e., orientation parallel to the coated surface, of metal flakes within the sintering, agent layer.

This latter behavior of the metal flakes is presumed to reduce the risk of damaging or destroying pressure-sensitive components, for example fragile components of components with a mechanically sensitive microstructure, during the sintering process.

The invention is illustrated through examples in the following, though these may not be construed such as to limit the invention in any way or form.

### EXAMPLES

1. Production of Metal Preparations According to the Invention

Firstly, metal preparations 1 to 3 according to the invention were produced by mixing the individual ingredients according to the following table. All amounts given are in units of % by weight.

| | Metal preparation | | |
|---|---|---|---|
| | 1 | 2 | 3 |
| Silver particles ¹⁾ | 70 | 62 | 45 |
| Exxsol ™ D60 | 15 | 19.5 | 14 |
| Terpineol | 14.7 | 18.1 | 39 |
| Ethylcellulose | 0.3 | 0.4 | 2 |
| Total | 100 | 100 | 100 |

¹⁾ Silver flakes having a mean particle diameter (d50) of 4.50 μm and a coating of 0.7% by weight octanoic acid/stearic acid (weight ratio 1:1)

2. Spray Application and Pressure Sintering of the Metal Preparations:

Metal preparations 1 to 3 were applied by spray application using a dispensing apparatus (dispensing apparatus DD-500 of DIMA, spray pressure 1.4 bar) into rectangular cavities 150 μm deep (4·6 mm²) of a silver-plated copper sheet 500 μm thick at a wet layer thickness of 30 μm. To protect the surfaces surrounding the cavities, a 100 μm-stainless steel stencil was arranged appropriately over the silver-plated copper sheet such that the cavities to be coated by spraying were situated right below the openings of the stencil.

The DD-500 dispensing apparatus was programmed such that the spray application involved targeted sampling of the stencil openings with as little over-spray being generated as possible. The motion speed of the spray organ was used to obtain a sintering agent layer of uniform thickness.

The thus partially spray coated silver-plated copper sheet was dried for 15 minutes at 120° C. object temperature in a convection drying cabinet to remove most of the solvent that had not evaporated during the spray application.

Then, the sintering agent, in the form of the dried metal preparation, was contacted to silicon chips having a silver contact surface (4·6 mm²). The subsequent sintering process proceeded at a sintering pressure of 20 MPa, a sintering temperature of 230° C., and a sintering time of 2 minutes. The sintering connection thus formed between the silicon chips and the silver-plated copper sheet attained satisfactory strength.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-15. (canceled)

16. A metal preparation comprising: (A) 40 to <80% by weight of at least one metal in the form of particles having a coating comprising at least one organic compound, and (B) >20 to 50% by weight organic solvent.

17. The metal preparation according, to claim 16, wherein the at least one metal is selected from the group consisting of copper, silver, gold, nickel, palladium, platinum, and aluminum.

18. The metal preparation according to claim 16, wherein the metal particles have the shape of flakes.

19. The metal preparation according to claim 16, wherein the at least one organic compound is selected from the group consisting of free fatty acids, fatty acid salts, and fatty acid esters.

20. The metal preparation according to claim 16, wherein the organic solvent (B) is a single organic solvent or a mixture of at least two organic solvents selected from terpineoles, N-methyl-2-pyrrolidone, ethylene glycol, dimethylacetamide, 1-tridecanol, 2-tridecanol, 3-tridecanol 4-tridecanol, 5-tridecanol, 6-tridecanol isotridecanol, 1-hydroxy-C16-C20-alkanes that are non-substituted with the exception of a methyl substitution on the penultimate carbon atom, dibasic esters, glycerol, diethylene glycol, triethylene glycol and aliphatic hydrocarbons having 5 to 32 carbon atoms.

21. The metal preparation according to claim 16, further comprising at least one metal precursor (C), 0 to 10 by weight of at least one sintering aid (D), and 0 to 15% by weight of one or more timber ingredients (E) selected from dispersion agents, surfactants:, dew foaming agents, binding agents, polymers and/or viscosity-controlling (rheological) agents.

22. The metal preparation according to claim 16, wherein the preparation has a viscosity in the range of 1 to 3 Pa·s, measured in accordance with DIN 53018 at 23° C., and a CSR measurement at a shear rate of D=10 s⁻¹.

23. A method for connecting components, comprising: (a) providing a sandwich arrangement comprising at least (a1) one component 1, (a2) one component 2, and (a3) a sintering agent situated between component 1 and component 2, and (b) sintering the sandwich arrangement, wherein the sintering agent is applied by spraying from a metal preparation according to claim 16.

24. The method according to claim 23, comprising d e steps of:
(i) providing at least two components 1 and 2;
(ii) spray application of the metal preparation onto a surface or surface fraction of at least one of the components, forming a contact surface while forming the sintering agent;
(iii) forming the sandwich arrangement by connecting the components with the sintering agent; and
(iv) sintering the sandwich arrangement.

25. The method according to claim 23, wherein the sintering is performed with or without pressure.

26. The method according to claim 23, wherein the components are electronics parts.

27. The method according to claim 23, wherein at least one of the components comprises a non-planar and/or suctioning and/or open-pore and/or a complicated surface topography-comprising surface or surface fraction, and wherein the sandwich arrangement is formed over the surface or the surface fraction.

28. The method according to claim 23, wherein the component surface(s) or surface fraction(s) to be provided with the sintering agent are heated before and/or during the spray application of the metal composition.

29. The method according to claim 23, wherein the spray application is selected from inkjet application, pneumatic spraying, and airless spraying.

30. The method according to claim 23, wherein the sintering agent comprises a wet layer thickness of 10 to 100 μm.
